(19) United States
(12) Patent Application Publication
(10) Pub. No.: US 2025/0331129 A1
(43) Pub. Date: Oct. 23, 2025

(54) FAN DETECTION SYSTEM AND METHOD

(71) Applicant: Lenovo (Beijing) Limited, Beijing (CN)

(72) Inventor: Jianguang JIN, Beijing (CN)

(21) Appl. No.: 19/185,912

(22) Filed: Apr. 22, 2025

(30) Foreign Application Priority Data
Apr. 22, 2024 (CN) 202410487720.9

(51) Int. Cl. H05K 7/20; G06F 1/20

(52) U.S. Cl. CPC H05K 7/20172; H05K 7/20209; G06F 1/203; G06F 2200/201

(57) ABSTRACT

A fan detection system including a fan unit, a fan connector unit, a sampling unit and a control chip, the fan unit being connected in series between the fan connector unit and the control chip, the fan connector unit being configured to send a first detection signal to the sampling unit based on a connection of the connected fan unit, the sampling unit being configured to sample the first detection signal to obtain a second detection signal, a voltage of the second detection signal being in a preset range, the control chip being configured to receive the second detection signal and determine a presence state and type of the fan unit based on the voltage of the second detection signal, the fan unit type including a single-rotor type and a dual-rotor type, and the first detection signal having a corresponding relationship with the fan unit type.

### CROSS-REFERENCES TO RELATED APPLICATION

This application claims priority to Chinese Patent Application No. 202410487720.9 filed on Apr. 22, 2024, the entire content of which is incorporated herein by reference.

### FIELD OF TECHNOLOGY

The present disclosure relates to the field of computer technology and, more specifically, to a fan detection system and method.

### BACKGROUND

Most electronic devices, such as personal computers, laptops, servers, etc., use fans for cooling. Through fan cooling, electronic devices can run smoothly. Thermal engineers can reasonably select single-rotor fans or dual-rotor fans for the thermal modules of the electronic device based on the thermal requirements of electronic device to maintain a balance between the normal operation of electronic device and the thermal dissipation of servers.

Often, before connecting a fan, the type of the connected fan must be manually configured in the electronic device system. As a result, the baseboard management controller (BM C) that controls the fan cannot actively learn the type of the newly connected fan, which is not conducive to achieving precise control of the fan.

### SUMMARY

One aspect of this disclosure provides a fan detection system. The fan detection system includes a fan unit, a fan connector unit, a sampling unit and a control chip. The fan unit is connected in series between the fan connector unit and the control chip. The fan connector unit is configured to send a first detection signal to the sampling unit based on a connection of the connected fan unit. The sampling unit is configured to sample the first detection signal to obtain a second detection signal, a voltage of the second detection signal being in a preset range. The control chip is configured to receive the second detection signal and determine a presence state and type of the fan unit based on the voltage of the second detection signal. The fan unit type includes a single-rotor type and a dual-rotor type, and the first detection signal has a corresponding relationship with the fan unit type.

Another aspect of this disclosure provides a fan detection method. The fan detection method includes sending, by a fan connector unit, a first detection signal to a sampling unit based on a connection between the fan connector unit and the sampling unit; performing, by the sampling unit, sampling processing on the first detection signal to obtain a second detection signal, a voltage of the second detection signal being in a preset range; and receiving, by a control chip, the second detection signal, and determining a presence state and type of a fan unit based on the voltage of the second detection signal.

Another aspect of this disclosure provides an electronic device. The electronic device includes a fan unit, a fan connector unit, a sampling unit and a control chip. The fan unit is connected in series between the fan connector unit and the control chip. The fan connector unit is configured to send a first detection signal to the sampling unit based on a connection of the connected fan unit. The sampling unit is configured to sample the first detection signal to obtain a second detection signal, a voltage of the second detection signal being in a preset range. The control chip is configured to receive the second detection signal and determine a presence state and type of the fan unit based on the voltage of the second detection signal. The fan unit type includes a single-rotor type and a dual-rotor type, and the first detection signal has a corresponding relationship with the fan unit type.

### BRIEF DESCRIPTION OF THE DRAWINGS

FIG. 1 is a schematic structural diagram of a fan detection system according to some embodiments of the present disclosure.

FIG. 2 is a schematic structural diagram of the fan detection system according to some embodiments of the present disclosure.

FIG. 3 is a schematic structural diagram of the fan detection system according to some embodiments of the present disclosure.

FIG. 4 is a schematic structural diagram of the fan detection system according to some embodiments of the present disclosure.

FIG. 5 is a flowchart of a fan detection method according to some embodiments of the present disclosure.

FIG. 6 is a flowchart of the fan detection method according to some embodiments of the present disclosure.

FIG. 7 is a flowchart of the fan detection method according to some embodiments of the present disclosure.

FIG. 8 is a flowchart of the liquid cooling control method according to some embodiments of the present disclosure.

### DETAILED DESCRIPTION

The features and technical solutions of present disclosure are described in detail with reference to the accompanying drawings in the accompanying drawings. The accompany drawings are for illustrative purposes and are not intended to limit the present disclosure.

Unless otherwise defined, all the technical and scientific terms used in the present disclosure have the same or similar meanings as generally understood by one of ordinary skill in the art. As described in the present disclosure, the terms used in the specification of the present disclosure are intended to describe example embodiments, instead of limiting the present disclosure.

In the present disclosure, description with reference to the terms “one embodiment,” “some embodiments,” “example,” “specific example,” or “some examples,” etc., means that specific features described in connection with the embodiment or example, structure, material or feature is included in at least one embodiment or example of the present disclosure. Furthermore, the particular features, structures, materials or characteristics described may be combined in any suitable manner in any one or more embodiments or examples. Furthermore, those skilled in the art may combine the different embodiments or examples described in this specification, as well as the features of the different embodiments or examples, as long as they do not conflict with each other.

In the present disclosure, the terms “first,” “second,” and “third” are only used for descriptive purposes, and should not be understood as indicating or implying relative importance or implying the number of indicated technical features. Thus, a feature described with “first,” “second,” and “third” may expressly or implicitly include at least this feature, and the order may be changed according to the actual situations.

For electronic devices such as personal notebooks and servers, heat is generally generated during operation. Therefore, heat dissipation is an important factor affecting the performance of electronic devices. In addition to cooling by adjusting the ambient temperature, there is also a need to design a cooling module containing multiple fans for the electronic device. During the operation of the electronic device, these fans need to adjust their speed based on the temperature of the electronic device to ensure that the electronic device can dissipate heat quickly.

At present, based on different configurations of the electronic device, different numbers of single-rotor fans and dual-rotor fans are selected to form a plurality of fans in a heat dissipation module. The speed of these fans can be controlled by the BMC, but engineers need to determine the type of the to-be-connected fans. After a fan is connected, the engineer must manually configure the type and other information of the newly connected fan in the BMC before the speed control can be performed. After a new fan is connected, whether the new fan is a single-rotor type or a dual-rotor type cannot be actively determined.

In view of the BMC not being able to determine the type of the newly connected fan, embodiments of the present disclosure provide a fan detection system and method. The fan connector unit can send a first detection signal to the sampling unit based on the connection state of the fan unit. Subsequently, the sampling unit can perform sampling based on the first detection signal to generate a second detection signal, and finally the control chip can determine the state and type of the fan unit based on the voltage of the second detection signal. Accordingly, the control chip can automatically obtain and determine the state and type of the fan unit after the fan unit is connected, thereby facilitating precise control of the fan and improving heat dissipation efficiency.

The present application is further described in detail below in conjunction with the accompanying drawings and specific embodiments.

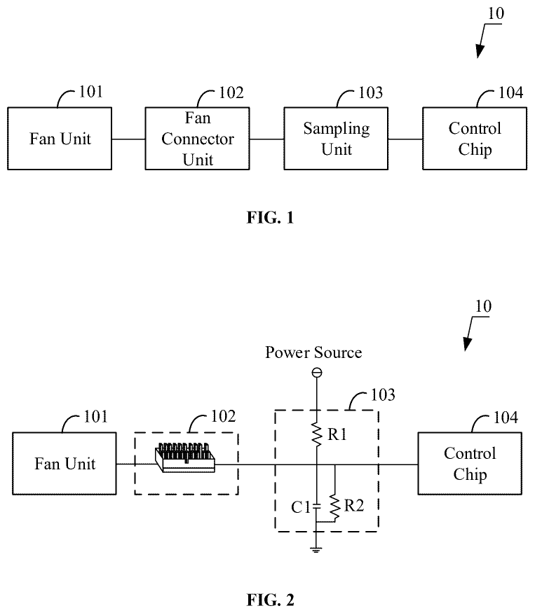

FIG. 1 is a schematic structural diagram of a fan detection system 10 according to some embodiments of the present disclosure. As shown in FIG. 1, the fan detection system 10 includes a fan unit 101, a fan connector unit 102, a sampling unit 103 and a control chip 104. The sampling unit 103 is connected in series between the fan connector unit 102 and the control chip 104.

In some embodiments, the fan connector unit 102 may be used to send a first detection signal to the sampling unit 103 based on the connection of the fan unit 101.

In some embodiments, the fan connector unit 102 may be a power connector disposed on a computer motherboard in an electronic device, and may be used to connect to an interface of the fan unit 101 to provide power and control signals to the fan unit 101 through the interface.

The fan unit 101 may be connected to the electronic device in a hot-plug manner through the interface provided by the fan connector unit 102. The fan unit 101 can send a detection signal to the control chip 104 through the sampling unit 103 in the electronic device, and receive a control signal of the control chip 104 through the sampling unit 103 and the fan connector unit 102. The control signal may be used to control the rotation speed and other states of the fan unit 101.

In some embodiments, the first detection signal may be a presence signal (e.g., the FAN_PRSN_N signal in different level states or different voltage ranges sent by the fan connector unit 102 based on the connection state of the fan unit 101 after the fan connector unit 102 detects that the fan unit 101 is connected or disconnected. For example, when the fan unit 101 is connected to the fan connector unit 102, the first detection signal may be in a first level state (e.g., the low level), and when the fan unit 101 is not connected to the fan connector unit 102, the first detection signal may be in a second level state (e.g., the high level). It can be understood that the corresponding relationship between the level state or voltage of the first detection signal and whether the fan unit 101 is connected can be determined based on specific circumstances, which is not limited in the embodiments of the present disclosure.

In some embodiments, the sampling unit 103 may be used to sample the first detection signal to obtain a second detection signal such that the voltage of the second detection signal can be in a preset range.

It should be noted that since the internal reference voltage of the control chip 104 is generally lower than the upper limit range of the voltage of the first detection signal, therefore, the sampling unit 103 may need to perform sampling processing on the first detection signal. More specifically, the voltage of the first detection signal can be proportionally reduced by means of resistor voltage division to generate the second detection signal that meets the preset range and then sent to the control chip 104. This avoids the voltage of the first detection signal from being too high to damage the control chip 104 if directly input into the control chip 104.

In some embodiments, the upper limit of the preset range may be determined based on the upper limit of the input voltage that the control chip 104 can receive. The upper limit of different types of control chips 104 may be different. In addition, the lower limit of the preset range may be determined based on the lower voltage limit of the first detection signal and the sampling capability of the sampling unit 103. In some cases, the lower limit of the preset range can be 0.

In some embodiments, the sampling unit 103 may be placed on a motherboard. The sampling unit 103 may include a plurality of resistors for voltage division, or other devices capable of performing sampling processing such as voltage division and voltage reduction, which are not limited in the embodiments of the present disclosure.

In some embodiments, the control chip 104 may be used to receive the second detection signal and determine the state and type of the fan unit 101 based on the voltage of the second detection signal. The types of the fan unit 101 may include a single-rotor type and a dual-rotor type, and the first detection signal may have a corresponding relationship with the type of the fan unit 101.

The control chip 104 may be disposed on the motherboard and connected to the fan connector unit 102 through the sampling unit 103. The control chip 104 may be an analog-to-digital converter (ADC) chip, or an ADC chip included in a BM C chip, or other chips with control and processing capabilities, which are not limited in the embodiments of the present disclosure.

It should be noted that, as described above, when the fan unit 101 is connected to or not connected to the fan connector unit 102, the first detection signal sent may also be in a different level state, that is, a different voltage range, and the corresponding second detection signal may also be in a different voltage range. Therefore, the presence state of the fan unit 101 may be determined based on the range of the voltage of the second detection signal. In some embodiments, the presence state may include present and not present.

It should also be noted that in some embodiments, the internal structure of the fan unit 101 may be designed. Accordingly, when the types of the fan unit 101 are different, the voltage of the first detection signal sent by the fan connector unit 102 can be in different ranges. Accordingly, the voltage of the corresponding second detection signal generated by the sampling unit 103 may also be correlated with the type of the fan unit 101. After the control chip 104 receives the second detection signal, it can determine whether the type of the fan unit 101 connected to the fan connector unit 102 is a single-rotor type or a dual-rotor type based on the range of the voltage of the second detection signal.

In some embodiments, the control chip 104 may first determine whether the fan unit 101 is present based on the voltage of the second detection signal. If the control chip 104 determines that the voltage of the second detection signal is within the voltage range corresponding to the fan unit 101 being present, then the second detection signal may be further determined to determine the fan type corresponding to the voltage range in which the voltage of the second detection signal is located, thereby determining the type of the fan unit 101.

A single-rotor type fan unit 101 is composed of one rotor and one motor, and a dual-rotor type fan unit 101 is composed of two rotors and one motor. The rotor is to the rotating part of the fan. Therefore, the dual-rotor type fan unit 101 can provide stronger wind force but greater noise than the single-rotor type fan unit 101. Generally, the number of single-rotor type fan units 101 and the number of dual-rotor type fan units 101 included in the fan detection system 10 can be configured based on the heat dissipation requirements. For each fan unit 101, the fan detection method provided in the embodiments of the present application can be used to determine the type and presence state of the fan unit 101.

Consistent with the present disclosure, the fan connector unit can send a first detection signal to the sampling unit based on the connection state of the fan unit, and the sampling unit can perform sampling based on the first detection signal to generate a second detection signal. Then, the control chip can determine the state and type of the fan unit based on the voltage of the second detection signal. Accordingly, the control chip can automatically obtain and determine the state and type of the fan unit, thereby facilitating precise control of the fan and improving heat dissipation efficiency.

Refer to FIG. 1. In some embodiments, the control chip 104 may be used to determine that the type of the fan unit 101 is a single-rotor type when the voltage of the second detection signal is detected to be within the first preset range. Or the control chip 104 may be used to determine that the type of the fan unit 101 is a dual-rotor type when the voltage of the second detection signal is detected to be within a second preset range.

It should be noted that, since the first detection signal is correlated with the type of the fan unit 101, the second detection signal obtained by sampling the first detection signal may also be correlated with the type of the fan unit 101. As described above, after determining that the voltage of the second detection signal is within the voltage range corresponding to the fan unit 101 being present, the second detection signal can be further determined. The type of the fan unit 101 can be determined based on whether the voltage of the second detection signal falls within the first preset range or the second preset range.

For example, the voltage range corresponding to the fan unit 101 being present may be less than or equal to 1.485 V. That is, when the voltage of the second detection signal is in the range of (0V, 1.485V), it can be determined that the fan unit 101 is connected to the fan connector unit 102. Further, the first preset range can be set to 1.1V, with upper and lower thresholds of 10%. That is, when the voltage of the second detection signal is in the range of (0.99V, 1.21V), it can be determined that the connected fan unit 101 is a single-rotor type. The second preset range can be set to 0.54V, with upper and lower thresholds of 10%. That is, when the voltage value of the second detection signal is in the range of (0.486V, 0.594V), it can be determined that the connected fan unit 101 is a dual-rotor type. It should be noted that the setting of the first preset range and the second preset range is only an example, and the actual setting needs can be determined based on the internal structure of the fan unit 101 and the sampling unit 103. In addition, the upper and lower floating thresholds of the voltage may be caused by the errors of the components in the fan unit 101 and the sampling unit 103. It is understood that due to the different precisions of different devices, the range of upper and lower thresholds may also vary.

It can be understood that the control chip 104 is configured to determine the voltage of the second detection signal generated after the first detection signal sent by the fan unit 101 is sampled by the sampling unit 103. However, the second detection signal is generated by sampling the first detection signal in proportion by the sampling unit 103. Therefore, when the types of the fan units 101 are different, the voltages of the first detection signal also belong to different preset ranges with relatively large differences. In some embodiments, when the upper limit of the voltage of the first detection signal can be directly input to the control chip 104, the control chip 104 may also set a corresponding preset range to directly determine the type of the fan unit 101 based on the voltage of the first detection signal.

Consistent with the present disclosure, control chip can determine the type of the fan unit based on whether the voltage of the second detection signal is within the first preset range or the second preset range, which allows the control chip to actively determine whether the connected fan unit is a single-rotor type or a dual-rotor type.

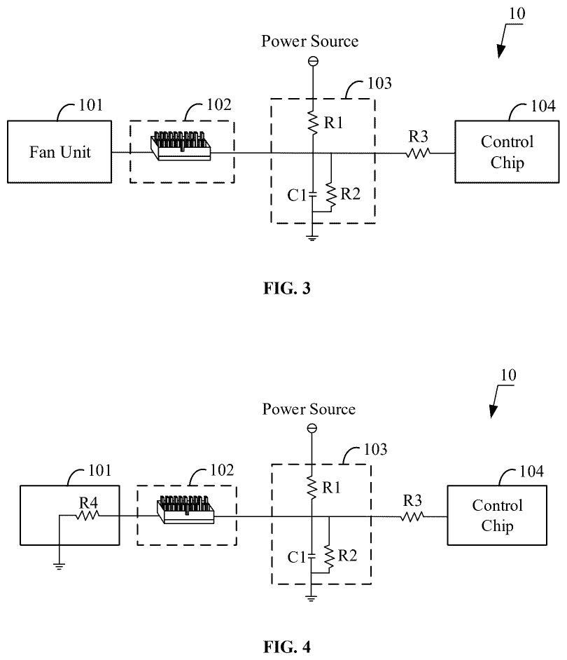

FIG. 2 is a schematic structural diagram of the fan detection system according to some embodiments of the present disclosure. As shown in FIG. 2, the sampling unit 103 includes a first resistor R1, a second resistor R2 and a first capacitor C1. The first end of the first resistor R1 is connected to a power source. The second end of the first resistor R1 is connected to the first end of the second resistor R2 and the first end of the first capacitor C1 respectively, and the second end of the first resistor R1 is also connected to the output of the fan connector unit 102 for receiving the first detection signal. The second end of the second resistor R2 and the second end of the first capacitor C1 are both grounded.

In some embodiments, the sampling unit 103 may be arranged on the motherboard, powered by a power source, and include a first resistor R1, a second resistor R2 and a first capacitor C1. The first resistor R1 and the second resistor R2 may be connected in series, the first end of the first resistor R1 may be connected to the power source, and the second end of the second resistor R2 may be grounded. Accordingly, by connecting the first detection signal between the first resistor R1 and the second resistor R2, the first detection signal can be sampled and processed by resistor voltage division such that the output second detection signal is reduced to a preset range. In some embodiments, the resistance of the first resistor R1 and the resistance of the second resistor R2 may be determined based on the voltage of the first detection signal and the preset range that the second detection signal needs to reach. For example, if the fan unit 101 is a single-rotor type, the second detection signal needs to be reduced to the first preset range (0.99V, 1.21V); or, if the fan unit 101 is a dual-rotor type, and the second detection signal needs to be reduced to the second preset range (0.486V, 0.594V), the resistance of the first resistor R1 can be set to 10K, and the resistance of the second resistor R2 can also be set to 10K.

In some embodiments, a first capacitor C1 may be connected in parallel across the second resistor R2 to filter and smooth the voltage signal. In other embodiments, a capacitor may also be connected in parallel at both ends of the first capacitor C1 to filter and smooth the voltage signal. For example, the capacitance of the first capacitor C1 may be 0.1 U.

It should be noted that for the same fan connector unit 102 and control chip 104, the sampling unit 103 may also be fixed. Accordingly, the sampling unit 103 can sample and process the first detection signals in different voltage ranges when different types of fan units 101 are connected, and generate second detection signals with voltages in different preset ranges.

It should also be noted that the circuit structure of the sampling circuit is only an example. In specific applications, any improvement can be made based on actual needs to realize the sampling function. Therefore, any improvement on the sampling circuit to achieve the same function is within the protection scope of this present disclosure.

Consistent with the present disclosure, the sampling unit can include a first resistor, a second resistor and a first capacitor. The sampling circuit can be configured to sample and process the first detection signal through voltage division to generate a second sampling signal, thereby avoiding the control chip from being damaged due to excessive voltage input to the control chip, thereby improving the stability of the system.

FIG. 3 is a schematic structural diagram of the fan detection system according to some embodiments of the present disclosure. As shown in FIG. 3, the sampling unit 103 further includes a third resistor R3. The first end of the third resistor R3 is connected to the second end of the first resistor R1, the first end of the second resistor R2, the first end of the first capacitor C1, and the output of the fan connector unit 102. The second end of the third resistor R3 is connected to the sampling pin of the control chip 104.

In some embodiments, when the sampling unit 103 further includes a third resistor R3, the first end of the third resistor R3 can be connected to an end of the sampling unit 103 outputting the second detection signal, and the second end of the third resistor R3 can be connected to the input end of the control chip 104. In this case, the first detection signal in the above embodiment can be used to further reduce the voltage of the signal after the first resistor R1 and the second resistor R2 are used to divide the first detection signal, generate a second detection signal, and send the second detection signal to the sampling pin of the control chip 104. In some embodiments, the sampling pin of the control chip 104 may be a pin for receiving the second detection signal.

It should be noted that the resistance of the third resistor R3 and whether the third resistor R3 needs to be set may be determined based on the resistances of the first resistor R1 and the second resistor R2, and the preset range that the voltage of the control chip 104 can receive must meet. It can be understood that if the voltage of the signal after the first detection signal is divided by the first resistor R1 and the second resistor R2 meets the preset range, the third resistor R3 can be set to zero or not. If the voltage of the signal after the first detection signal is divided by the first resistor R1 and the second resistor R2 is still higher than the upper limit of the preset range, the resistance of the third resistor R3 can be set based on the voltage of the signal after the first detection signal is divided by the first resistor R1 and the second resistor R2, and the upper limit of the preset range.

In addition, the third resistor R3 may also adjust the impedance of the circuit in the system, and the impedance may be equal to the resistance of the third resistor R3.

Consistent with the present disclosure, a third resistor can be added to the sampling unit to ensure that the second detection signal output by the sampling unit can meet the preset range to avoid the voltage of the second detection signal being too large and causing damage to the control chip.

FIG. 4 is a schematic structural diagram of the fan detection system according to some embodiments of the present disclosure. As shown in FIG. 4, the fan unit 101 includes a fourth resistor R4. The first end of the fourth resistor R4 is grounded, and the second end of the fourth resistor R4 is connected to the fan connector unit 102. When the types of the fan unit 101 are different, the resistance of the fourth resistor R4 may be different.

In some embodiments, the hardware structure of the fan unit 101 may be improved such that when the fan unit 101 is of different types, the voltage of the first detection signal generated by the fan connector unit 102 can be in different ranges. For example, referring to FIG. 4, a fourth resistor R4 is arranged in the fan unit 101 at an interface position connected to the fan connector unit 102. After the fan unit 101 is connected to the fan connector unit 102, the first end of the fourth resistor R4 is grounded, and the second end of the fourth resistor R4 is connected to the fan connector unit 102. In the embodiments of the present disclosure, when the type of the fan unit 101 is different, the resistance of the fourth resistor R4 may be different, but the voltage of the present signal generated by the fan connector unit 102 after being connected to the fan unit 101 is fixed. Accordingly, the fourth resistor R4 can divide the voltage of the present signal such that the fan connector unit 102 can generate first detection signals with different voltages when different types of fan units 101 are connected.

For example, in some embodiments, for a single-rotor fan unit 101, the resistance of the fourth resistor R4 may be set to 10K; for a dual-rotor fan unit 101, the resistance of the fourth resistor R4 may be set to 2.43K. In some embodiments, the accuracy of the fourth resistor R4 may be 1%.

Accordingly, after the single-rotor type fan unit 101 is connected to the fan connector unit 102, the fan connector unit 102 can be connected to the fourth resistor R4 of 10K. The first detection signal generated can be sampled and processed by the sampling unit 103 to generate a second detection signal that meets the first preset range (0.99V, 1.21V) and output to the control chip 104. Alternatively, after the dual-rotor fan unit 101 is connected to the fan connector unit 102, the fan connector unit 102 can be connected to the fourth resistor R4 of 2.43K. The first detection signal generated can be sampled and processed by the sampling unit 103 to generate a second detection signal that is in the second preset range (0.486V, 0.594V) and output to the control chip 104.

Consistent with the present disclosure, the hardware structure of the fan unit is improved. After different types of fan units are connected, the voltages of the generated first detection signals can be in different ranges, thereby causing the sampled second detection signals to also be in different ranges. Accordingly, the control chip can determine whether the connected fan unit is a single-rotor type or a dual-rotor type based on the range of the voltage of the second detection signal.

Refer to FIG. 4. In some embodiments, the fan unit 101 may be configured to send a third detection signal to the sampling unit 103. The third detection signal may be used to indicate the current speed of the fan unit 101.

In some embodiments, the third detection signal may be a tachometer (TACH) signal, which is a square wave signal with variable frequency. A Hall sensor may be arranged next to the rotor in the fan unit 101. When the motor controls the rotor to rotate, the magnet of the motor rotor passes through the Hall sensor and output a high level. After signal processing, the fan unit 101 can output a square wave, that is, the third detection signal, to the sampling unit 103 via the fan connector unit 102.

In some embodiments, the sampling unit 103 may be further configured to sample the third detection signal to obtain a fourth detection signal such that the voltage of the fourth detection signal can be in the preset range.

In some embodiments, after receiving the third detection signal, the sampling unit 103 can divide the third detection signal based on the multiple resistors in the sampling unit 103 in the same manner described above to generate a fourth detection signal and send the fourth detection signal to the control chip 104. In some embodiments, the frequency of the fourth detection chip may be the same as the frequency of the third detection chip.

In some embodiments, the hardware structure of the sampling unit 103 may be the same as the structure for sampling processing the first detection signal described in the foregoing embodiments.

In some embodiments, the control chip 104 may be configured to receive a fourth detection signal, determine a current rotation speed of the fan unit 101 based on the fourth detection signal, and determine whether the fan unit 101 is faulty based on a comparison result between the current rotation speed and a set threshold.

In some embodiments, the control chip 104 may sample the frequency of the fourth detection signal after receiving the fourth detection signal based on the preset frequency of the third detection signal. A counter may be arranged and incremented by one in each clock cycle. The control chip 104 may determine the current rotation speed of the fan unit 101 based on the value of the counter.

In addition, the control chip 104 may compare the current speed with the set threshold. If the current speed of the fan unit 101 is not within the set threshold, the fan unit 101 can be as faulty. In this case, the control chip 104 can issue an alarm to notify the staff to repair the fan unit 101. In some embodiments, the set threshold may be a rotation speed range that a normally operating fan should be in, and is stored in the control chip 104.

Based on the description above, the control chip 104 can determine whether the fan unit 101 is present and whether the connected fan unit 101 is a single-rotor type or a dual-rotor type based on the second detection signal generated by performing sampling processing the first detection signal. The control chip 104 can also determine whether the fan unit 101 is faulty based on the fourth detection signal generated by performing sampling processing the third detection signal. The process of the control chip 104 determining whether the fan unit 101 is faulty may be the process of the control chip 104 determining the presence state and the type of the fan unit 101, or after the process of the control chip 104 determining the presence state and type of the fan unit 101, or before the process of the control chip 104 determining the in-position state and type of the fan unit 101, which is not limited in the embodiments of the present disclosure.

The above embodiment is based on the situation where the voltage of the third detection signal output by the fan unit 101 is higher than the aforementioned preset range, where the preset range is the upper and lower limits of the voltage of the signal that the control chip 104 can receive. When the voltage of the third detection signal output by the fan unit 101 meets the preset range described above, the fan unit 101 may be directly connected to the control chip 104 through the fan connector unit 102, and the third detection signal may be directly input to the control chip 104.

Consistent with the present disclosure, the fan unit can output the third detection signal to the sampling unit, and the sampling unit can generate a fourth detection signal after sampling processing such that the control chip can determine whether the fan unit is faulty based on the fourth detection signal. Accordingly, the control chip can detect abnormal fans in time and issue an alarm, thereby improving the safety and stability of the system.

Refer to FIG. 4. In some embodiments, the control chip 104 may be configured to determine that the fan unit 101 is in an absent state and issue a first prompt message when it is detected that the voltage of the second detection signal is in a third preset range. The first prompt information may be used to prompt the user that the fan unit 101 is absent.

As described above, the first detection signal will be generated whether the 101 is connected to the fan connector unit 102. However, when the fan unit 101 is connected and not connected, the voltage of the first detection signal generated is in different ranges, and the voltage of the second detection signal generated after sampling processing is also in different ranges. In some embodiments, when the fan unit 101 is not connected to the fan connector unit 102, the range of the second detection signal corresponding to the first detection signal generated may be set as the third preset range.

The third preset range may be determined based on the actual hardware structure of the sampling unit 103. For example, when the sampling unit 103 includes the first resistor R1 with a resistance of 10K, the second resistor R2 with a resistance of 10K, and the first capacitor C1 with a capacitance of 0.1U, the third preset range may be set to 1.65V, with upper and lower thresholds of 10%. That is, the third preset range may be (1.485V, 1.815V). It should be noted that the upper and lower thresholds may be determined based on the accuracy of the device in the sampling unit 103, resulting in the deviation of the fourth detection signal.

That is, after the control chip 104 determines that the received second detection signal is within the third preset range, it determines that the presence state of the fan unit 101 is the absent state. Subsequently, the control chip 104 may send a first prompt message to the user, informing the user that the fan unit 101 is not in place. In some embodiments, the first prompt information may be sent through an interactive interface, sound, etc., which is not limited in the embodiments of the present disclosure.

In some embodiments, after determining that the second detection signal is not within the third preset range, the control chip 104 may determine that the fan unit 101 is in the present state. Further, when the control chip 104 determines that the second detection signal is within the first preset range, it may determine that the type of the fan unit 101 is a single rotor type. If the control chip 104 determines that the voltage of the second detection signal is not within the first preset range, it may further determine whether the voltage of the second detection signal is within the second preset range. If the voltage of the second detection signal is within the second preset range, it is determined that the type of the fan unit 101 is a dual-rotor type. Otherwise, if it is not within the second preset range, it is determined that the fan unit 101 is abnormal. The abnormalities may include the fan unit 101 not in this project, that is, the unknown fan unit 101, and the fan unit 101 is faulty. That is, in the embodiments of the present application, the control chip 104 may also determine whether the fan unit 101 is faulty based on the voltage value of the second detection signal.

Consistent with the present disclosure, when the voltage of the second detection signal is within the third preset range, the corresponding fan unit can be determined to be not in place such that the control chip can actively detect the presence state of the fan unit, which is convenient for controlling the fan unit.

Refer to FIG. 4. In some embodiments, when the control chip 104 is the first chip type, the control chip 104 may be further used to obtain a first reference voltage currently in use, and determine a first upper limit voltage corresponding to the second detection signal based on the first reference voltage.

The first type of chip may be an ADC chip built into the BMC. The internal reference voltage of the chip is 2.5V, and the voltage of the input signal cannot exceed ¾ of the internal reference voltage, that is, 1.875V.

Therefore, in the embodiments of the present disclosure, when the control chip 104 is the first chip type, the first reference voltage value may be determined to be 2.5V. Based on the above input signal, that is, the corresponding calculation relationship between the voltage of the second detection signal and the first reference voltage, the first upper limit voltage corresponding to the second detection signal can be determined to be 1.875V. That is, in the hardware design stage, it is determined to use the first type of chip, the resistances of the resistors in the sampling unit 103 and the fan unit 101 may need to be adjusted. Accordingly, after the first detection signal is divided by the plurality of resistors in the sampling unit 103 and the fan unit 101, the maximum voltage of the second detection signal obtained can be lower than the first upper limit voltage.

Refer to FIG. 4. In some embodiments, when the control chip 104 is a second chip type, the control chip 104 may be further configured to obtain a second reference voltage currently in use, and determine a second upper limit voltage corresponding to the second detection signal based on the second reference voltage.

In some embodiments, the second type of chip may be an ADC128 chip (integrated circuit chip, IC). The internal reference voltage of this chip is 2.56V, and the voltage of the input signal cannot exceed the internal reference voltage of 2.56-3 LSb/2, that is, 2.559V. LSb=VREF/2¹², VREF=2.56V, that is, the internal reference voltage. Accordingly, 3 LSb/2=3×2.56/(2×2¹²)=0.00097, therefore, 2.56-3 LSb/2=2.559V.

Therefore, in the embodiments of the present disclosure, when the control chip 104 is the first chip type, the first reference voltage value may be determined to be 2.56V. Based on the above input signal, that is, the corresponding calculation relationship between the voltage of the second detection signal and the first reference voltage, the second upper limit voltage corresponding to the third detection signal can be determined to be 2.559V. That is, in the hardware design stage, if it is determined to use the second type of chip, the resistances of the resistors in the sampling unit 103 and the fan unit 101 may need to be adjusted. Accordingly, after the first detection signal is divided by the plurality of resistors in the sampling unit 103 and the fan unit 101, the maximum voltage of the second detection signal obtained can be lower than the second upper limit voltage.

It should also be noted that the control chip 104 being a first chip type or a second chip type is only an example. In actual application scenarios, the control chip 104 may also be other types of chips. In this case, the reference voltage may be determined based on the internal reference voltage of the control chip 104, and the upper limit voltage may be determined based on the maximum voltage that the control chip 104 can input. The maximum volage that the control chip 104 can input is not limited in the embodiments of the present disclosure.

Consistent with the present disclosure, when the types of the control chip are different, the upper limit voltage of the second detection signal may be designed to be different such that the system can still maintain stable operation when the control chip changes, thereby improving the stability and flexibility of the system.

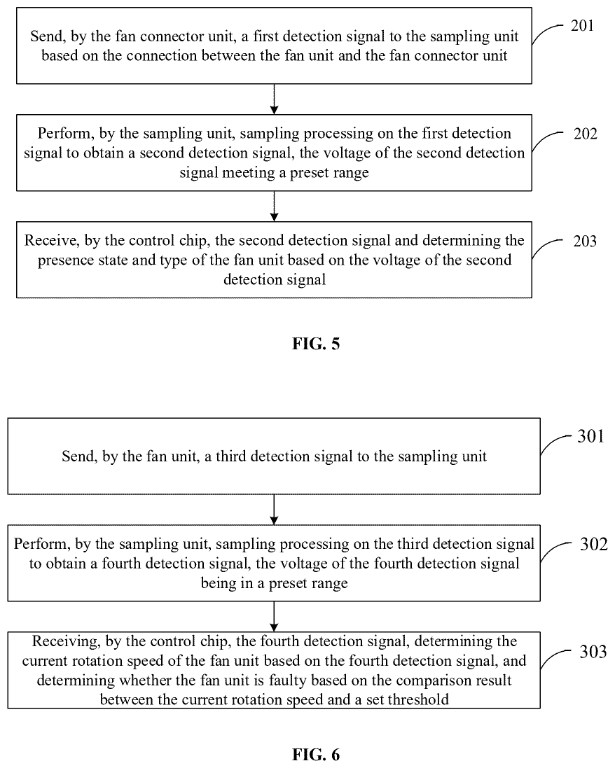

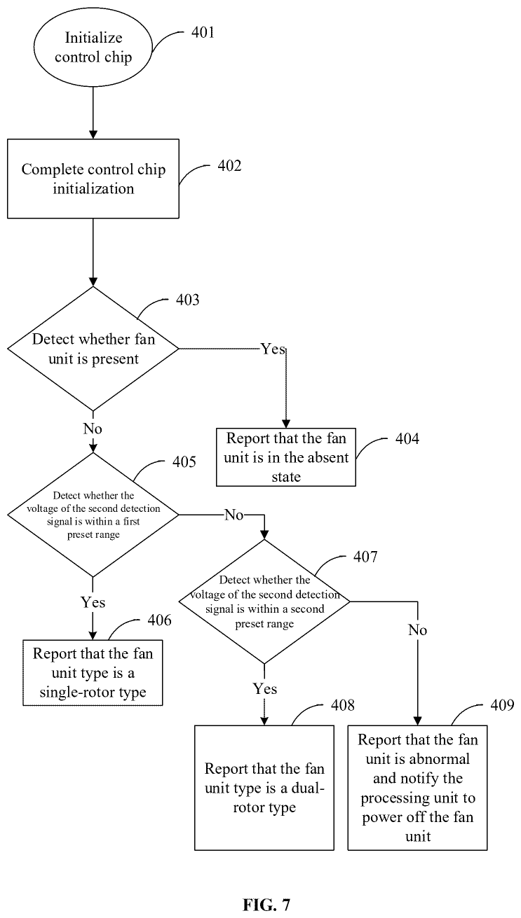

FIG. 5 is a flowchart of a fan detection method according to some embodiments of the present disclosure. The fan detection method can be applied to the fan detection system described in the foregoing embodiments. The method will be described in detail below.
201, sending, by the fan connector unit, a first detection signal to the sampling unit based on the connection between the fan unit and the fan connector unit.
202, performing, by the sampling unit, sampling processing on the first detection signal to obtain a second detection signal, the voltage of the second detection signal being in a preset range.
203, receiving, by the control chip, the second detection signal and determining the presence state and type of the fan unit based on the voltage of the second detection signal.

In some embodiments, types of fan units may include a single-rotor type and a dual-rotor type, and the first detection signal may have a corresponding relationship with the type of the fan unit

FIG. 6 is a flowchart of the fan detection method according to some embodiments of the present disclosure. The method will be described in detail below.
301, sending, by the fan unit, a third detection signal to the sampling unit.

In some embodiments, the third detection signal may be used to indicate the current speed of the fan unit.
302, performing, by the sampling unit, sampling processing on the third detection signal to obtain a fourth detection signal to cause the voltage of the fourth detection signal to be in a preset range.
303, receiving, by the control chip, the fourth detection signal, determining the current rotation speed of the fan unit based on the fourth detection signal, and determining whether the fan unit is faulty based on the comparison result between the current rotation speed and a set threshold.

In some embodiments, the fan detection method may further include, when the control chip detects that the voltage of the second detection signal is within a third preset range, determining that the fan unit is in absent state and issuing a first prompt message.

In some embodiments, the first prompt information may be used to prompt the user that the fan unit is not in place.

In some embodiments, the fan detection method may further include, when the control chip is a first chip type, using the control chip to obtain the first reference voltage currently used, and determining the first upper limit voltage corresponding to the second detection signal based on first reference voltage.

In some embodiments, the fan detection method may further include, when the control chip is a second chip type, using the control chip to obtain the second reference voltage currently used, and determining the second upper limit voltage corresponding to the second detection signal based on the second reference voltage.

Consistent with the present disclosure, the fan connector unit can send a first detection signal to the sampling unit based on the presence state of the fan unit, and then the sampling unit can perform sampling based on the first detection signal to generate a second detection signal. Subsequently, the control chip can determine the state and type of the fan unit based on the voltage of the second detection signal, and can also determine whether the fan is faulty based on the fourth detection signal. Accordingly, the control chip can automatically obtain and determine the fan unit's state, type, and whether it is faulty after the fan unit is connected, making it easier to achieve precise control of the fan and improve heat dissipation efficiency.

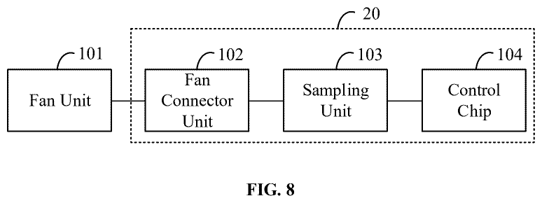

FIG. 7 is a flowchart of the fan detection method according to some embodiments of the present disclosure. The method will be described in detail below.
401, initializing the control chip.

In some embodiments, the control chip may be the ADC chip in the BMC, or the ADC128 chip
402, completing control chip initialization.
403, detecting whether the fan unit is present; if so, proceed to the process at 404, otherwise, proceed to the process at 405.

In some embodiments, based on whether the fan unit is present may be determined by determining whether the second detection signal is within the range of 1.65V, with 10% of the upper and lower thresholds, that is, the third preset range (1.485V, 1.815V). For example, if the second detection signal is not within the third preset range, it is determined that the fan unit is in the present state, and the process at 404 can be performed; if the second detection signal is within the third preset range, it is determined that the fan unit is the absent state, and the process at 405 can be performed.

It should be noted that the BMC ADC currently uses an internal reference voltage (2.5V), and the A DC input cannot exceed ¾ of the reference voltage (1.875V); when the ADC128 IC uses an internal reference voltage (2.56V), the ADC input cannot exceed 2.56V-3 LSb/2 of the reference voltage (2.559V). Therefore, the voltage of the second detection signal needs to be determined based on the type of the control chip.
404, reporting that the fan unit is in the absent state.
405, detecting whether the voltage of the second detection signal is within a first preset range. If so, proceed to the process at 406; otherwise, proceed to the process at 407.

In some embodiments, a series resistor may be added to the presence signal of the fan unit, the resistance may be set based on the single-rotor and dual-rotor settings.

In some embodiments, when a 10K (1%) resistor is added to the single-rotor fan module, the first preset range may be set to 1.1V, with upper and lower thresholds of 10%. That is, when the voltage of the second detection signal is within the first preset range (0.99V, 1.21V), it can be determined that the connected fan unit is a single-rotor type, and process at 406 can be performed. Otherwise, if the voltage of the second detection signal is not within the first preset range, and the process at 407 can be performed.
406, reporting that the fan unit type is a single-rotor type.
407, detecting whether the voltage of the second detection signal is within a second preset range. If so, proceed to the process at 408; otherwise, proceed to the process at 409.

In some embodiments, when a 2.43K (1%) resistor is added to the dual-rotor fan module, the second preset range may be set to 0.54V, with upper and lower thresholds of 10%. That is, when the voltage of the second detection signal is within the second preset range (0.486V, 0.594V), it can be determined that the connected fan unit is a dual-rotor type, and the process at 408 can be performed. Otherwise, if the voltage of the second detection signal is not within the second preset range, the process at 409 can be performed.
408, reporting that the fan unit is a dual-rotor type.
409, reporting that the fan unit is abnormal, and notifying the processing unit to power off the fan unit.

In some embodiments, the processing unit may be a field-programmable gate array (FPGA), which is communicatively connected to the control chip.

FIG. 8 is a flowchart of the liquid cooling control method according to some embodiments of the present disclosure. As shown in FIG. 8, the electronic device 20 includes the sampling unit 103, the fan connector unit 102 and the control chip 104 described in the foregoing embodiments, and the fan unit 101 is connected to the fan connector unit 102 on the electronic device 20 in a hot-swappable manner.

It should be noted that whether the fan unit 101 is connected to the fan connector unit 102, the fan connector unit 102 will generate a first detection signal to the sampling unit 103, but the voltage range of the first detection signal generated may be different when the fan unit 101 is connected or unplugged.

In some embodiments, the sampling unit 103 may be configured to perform sampling processing on the first detection signal to obtain a second detection signal. The maximum voltage of the second detection signal may need to be lower than the upper voltage limit that the control chip 104 can receive.

The control chip 104 may determine that the fan unit 101 is in the absent state when detecting that the voltage of the second detection signal is within the third preset range. When it is detected that the voltage of the second detection signal is within the first preset range, the type of the fan unit 101 can be determined to be a single-rotor type, or when it is detected that the voltage of the second detection signal is within the second preset range, the type of the fan unit 101 can be determined to be a dual-rotor type.

In the above process, the control chip 104 may also determine whether the fan unit 101 is faulty based on the third detection signal sent by the fan unit.

Those of ordinary skill in the art may be aware that the units and algorithm steps of the examples described in embodiments of the present disclosure may be implemented by electronic hardware or a combination of computer software and electronic hardware. Whether these functions are executed by hardware or software depends on the specific application and design constraint conditions of the technical solution. Those of skill in the art may.3 use different methods for each specific application to implement the described functions, but such implementation should not be considered beyond the scope of the present disclosure.

Those skilled in the art can understand that, for the convenience and brevity of description, for the specific working processes of the devices and units described above, reference can be made to the corresponding processes in the foregoing method embodiments and will not be repeated here.

In the present disclosure, the terms “include”, “contain” or other alternatives shall be non-exclusiveness, the inclusion of a series of element such as process, method, object or equipment shall include not only the already mentioned elements but also those elements not mentioned, and shall include the elements which are inherent in the process, method, object or equipment. However, under the condition of no more limitations, the definition of an essential element limited by the sentence “including a . . . ” shall not obviate that in addition to containing the said essential element in the process, method, object or equipment, other essential element of the same nature may also exist in the above-mentioned process, method, object or equipment.

The sequence of the embodiments of the present disclosure are merely for ease of description, and do not imply the preference of the embodiments.

The methods disclosed in the method embodiments of the present disclosure may be arbitrarily combined without conflict to obtain new method embodiments.

The features disclosed in the product embodiments of the present disclosure may be combined arbitrarily without conflicts to obtain new product embodiments.

The features disclosed in the method or device embodiments of the present disclosure may be combined arbitrarily without conflict to obtain new embodiments or device embodiments.

The above descriptions are merely example embodiments of the present disclosure, and are not intended to limit the scope of the present disclosure. Any equivalent modification made to the structure or processes based on content of this specification and the accompanying drawings for direct or indirect use in other related technical fields shall all fall within the scope of the present disclosure.

What is claimed is:

1. A fan detection system comprising:
a fan unit;
a fan connector unit;
a sampling unit; and
a control chip, the fan unit being connected in series between the fan connector unit and the control chip, wherein:
the fan connector unit is configured to send a first detection signal to the sampling unit based on a connection of the connected fan unit;
the sampling unit is configured to sample the first detection signal to obtain a second detection signal, a voltage of the second detection signal being in a preset range; and
the control chip is configured to receive the second detection signal and determine a presence state and type of the fan unit based on the voltage of the second detection signal, the fan unit type including a single-rotor type and a dual-rotor type, the first detection signal having a corresponding relationship with the fan unit type.

2. The system of claim 1, wherein:
the control chip is configured to determine that the fan unit type is the single-rotor type when it is detected that the voltage of the second detection signal is within a first preset range; or,
the control chip is configured to determine that the fan unit type is the dual-rotor type when it is detected that the voltage of the second detection signal is within a second preset range.

3. The system of claim 1, wherein:
the sampling unit includes a first resistor, a second resistor and a first capacitor, wherein:
a first end of the first resistor is connected to a power source;
a second end of the first resistor is respectively connected to a first end of the second resistor and a first end of the first capacitor, and the second end of the first resistor is also connected to an output of the fan connector unit for receiving the first detection signal; and
a second end of the second resistor and a second end of the first capacitor are both grounded.

4. The system of claim 3, wherein:
the sampling unit includes a third resistor, wherein:
a first end of the third resistor is respectively connected to the second end of the first resistor, the first end of the second resistor, the first end of the first capacitor, and the output of the fan connector unit; and
a second end of the third resistor is connected to a sampling pin of the control chip.

5. The system of claim 1, wherein:
the fan unit includes a fourth resistor, wherein:
a first end of the fourth resistor is grounded, and a second end of the fourth resistor is connected to the fan connector unit, a resistance of the fourth resistor being different when the types of fan units are different.

6. The system of claim 1, wherein:
the fan unit is further configured to send a third detection signal to the sampling unit, the third detection signal being used to represent a current speed of the fan unit;
the sampling unit is further configured to sample the third detection signal to obtain a fourth detection signal, a volage of the fourth detection signal being in the preset range; and
the control chip is further configured to receive the fourth detection signal, determine the current rotation speed of the fan unit based on the fourth detection signal, and determine whether the fan unit is faulty based on a comparison result of the current rotation speed and a set threshold.

7. The system of claim 1, wherein:
the control chip is further configured to determine that the fan unit is in an absent state when the voltage of the second detection signal is detected to be within a third preset range, and to issue a first prompt message, the first prompt message being used to prompt a user that the fan unit is in the absent state.

8. The system of claim 1, wherein:
when the control chip is a first chip type, the control chip is further configured to obtain a first reference voltage currently in use, and determine a first upper limit voltage corresponding to the second detection signal based on the first reference voltage.

9. The system of claim 1, wherein:
when the control chip is a second chip type, the control chip is further configured to obtain a second reference voltage currently in use, and determine a second upper limit voltage corresponding to the second detection signal based on the second reference voltage.

10. A fan unit detection method comprising:
sending, by a fan connector unit, a first detection signal to a sampling unit based on a connection between the fan connector unit and the sampling unit;
performing, by the sampling unit, sampling processing on the first detection signal to obtain a second detection signal, a voltage of the second detection signal being in a preset range; and
receiving, by a control chip, the second detection signal, and determining a presence state and type of a fan unit based on the voltage of the second detection signal.

11. The method of claim 10, wherein:
the control chip is configured to determine that the fan unit type is the single-rotor type when it is detected that the voltage of the second detection signal is within a first preset range; or,
the control chip is configured to determine that the fan unit type is the dual-rotor type when it is detected that the voltage of the second detection signal is within a second preset range.

12. The method of claim 10, wherein:
the sampling unit includes a first resistor, a second resistor and a first capacitor, wherein:
a first end of the first resistor is connected to a power source;
a second end of the first resistor is respectively connected to a first end of the second resistor and a first end of the first capacitor, and the second end of the first resistor is also connected to an output of the fan connector unit for receiving the first detection signal; and
a second end of the second resistor and a second end of the first capacitor are both grounded.

13. The method of claim 12, wherein:
the sampling unit includes a third resistor, wherein:
a first end of the third resistor is respectively connected to the second end of the first resistor, the first end of the second resistor, the first end of the first capacitor, and the output of the fan connector unit; and
a second end of the third resistor is connected to a sampling pin of the control chip.

14. The method of claim 10, wherein:
the fan unit includes a fourth resistor, wherein:
a first end of the fourth resistor is grounded, and a second end of the fourth resistor is connected to the fan connector unit, a resistance of the fourth resistor being different when the types of fan units are different.

15. The method of claim 10 further comprising:
sending, by the fan unit, a third detection signal to the sampling unit, the third detection signal being used to represent a current speed of the fan unit;
performing, by the sampling unit, sampling processing on the third detection signal to obtain a fourth detection signal, a voltage of the fourth detection signal being in the preset range; and
receiving, by the control chip, the fourth detection signal, determining the current rotation speed of the fan unit based on the fourth detection signal, and determining whether the fan unit is faulty based on the comparison result between the current rotation speed and a set threshold.

16. The method of claim 10, wherein:
the control chip is further configured to determine that the fan unit is in an absent state when the voltage of the second detection signal is detected to be within a third preset range, and to issue a first prompt message, the first prompt message being used to prompt a user that the fan unit is in the absent state.

17. The method of claim 10, wherein:
when the control chip is a first chip type, the control chip is further configured to obtain a first reference voltage currently in use, and determine a first upper limit voltage corresponding to the second detection signal based on the first reference voltage.

18. The method of claim 10, wherein:
when the control chip is a second chip type, the control chip is further configured to obtain a second reference voltage currently in use, and determine a second upper limit voltage corresponding to the second detection signal based on the second reference voltage.

19. An electronic device comprising:
a fan unit;
a fan connector unit;
a sampling unit; and
a control chip, the fan unit being connected in series between the fan connector unit and the control chip, wherein:
the fan connector unit is configured to send a first detection signal to the sampling unit based on a connection of the connected fan unit;
the sampling unit is configured to sample the first detection signal to obtain a second detection signal, a voltage of the second detection signal being in a preset range; and
the control chip is configured to receive the second detection signal and determine a presence state and type of the fan unit based on the voltage of the second detection signal, the fan unit type including a single-rotor type and a dual-rotor type, the first detection signal having a corresponding relationship with the fan unit type.

20. The electronic device of claim 19, wherein:
the control chip is configured to determine that the fan unit type is the single-rotor type when it is detected that the voltage of the second detection signal is within a first preset range; or,
the control chip is configured to determine that the fan unit type is the dual-rotor type when it is detected that the voltage of the second detection signal is within a second preset range.
